(19) United States
(12) Patent Application Publication
(10) Pub. No.: US 2016/0099544 A1
(43) Pub. Date: Apr. 7, 2016

(54) LASER APPARATUS

(71) Applicant: CANON KABUSHIKI KAISHA, Tokyo (JP)

(72) Inventor: Katsuyuki Hoshino, Kawasaki-shi (JP)

(21) Appl. No.: 14/851,329

(22) Filed: Sep. 11, 2015

(30) Foreign Application Priority Data
Oct. 3, 2014 (JP) 2014-204453

(51) Int. Cl. H01S 5/06; G01N 21/63; H01S 5/183

(52) U.S. Cl. CPC H01S 5/0604; H01S 5/183; G01N 21/63

(57) ABSTRACT

A laser apparatus including an active medium, an optical cavity, a wavelength conversion medium, an excitation light source, a first reflector and a second reflector, wherein the active medium and the wavelength conversion medium are arranged between the first reflector and the second reflector, excitation light with a center wavelength λ1 emitted from the excitation light source is caused to enter the wavelength conversion medium through the first reflector, the wavelength conversion medium generates wavelength-converted light with a center wavelength λ2 by entrance of the excitation light, the first reflector and the second reflector reflect the wavelength-converted light, the active medium is photoexcited by at least the wavelength-converted light to emit light, and the laser apparatus causes resonance of the light by the optical cavity to generate laser light with a center wavelength λ3.

### BACKGROUND OF THE INVENTION

1. Field of the Invention

The present invention relates to a laser apparatus.

2. Description of the Related Art

Laser apparatuses in which laser oscillation of an active medium is generated by light excitation are widely used today. Particularly, a laser apparatus using a solid-state laser crystal as the active medium to cause photoexcitation of the solid-state laser crystal with a semiconductor laser is used for various purposes because the laser apparatus is easy to downsize.

In order to improve the laser output and overall efficiency of a laser apparatus, it is necessary to cause an active medium to absorb excitation light efficiently. Japanese Patent Application Laid-Open No. 2000-101169 discloses a technique of reflecting excitation light emitted from an excitation light source many times to improve the absorption efficiency of excitation light with respect to an active medium. Specifically, the transmitted excitation light without being absorbed into the active medium is reflected by a reflector for reflecting excitation light to reenter the active medium and then is absorbed into the active medium, thus achieving an improvement in the absorption efficiency of the excitation light.

However, as will be described below, the laser apparatus described in Japanese Patent Application Laid-Open No. 2000-101169 in the above conventional example destabilizes the operation of the excitation light source for emitting excitation light, and this has a problem that the laser output of the laser apparatus becomes unstable.

In detail, in the laser apparatus described in Japanese Patent Application Laid-Open No. 2000-101169, an excitation light source made up of multiple semiconductor lasers arranged in parallel and a reflector for reflecting excitation light emitted from the excitation light source are arranged symmetrically with respect to the active medium.

Here, a heatsink is placed between adjacent ones of the multiple semiconductor lasers, and a highly reflective coat for reflecting the excitation light is applied to a surface of the heatsink on the side to emit the excitation light.

As a result, the excitation light emitted from the excitation light source is reflected many times between the reflector and the heatsink with the applied highly reflective coat so that the absorption efficiency of the excitation light with respect to the active medium can be improved.

In the meantime, part of excitation light reflected by the reflector becomes return light that returns to the inside of the semiconductor lasers.

Therefore, the return light is coupled to an active region of the semiconductor lasers, and this affects the oscillation of the semiconductor lasers themselves, causing a problem that the operation of the semiconductor lasers becomes unstable.

### SUMMARY OF THE INVENTION

The present invention has been made in view of the above problems, and it is an object thereof to provide a laser apparatus capable of suppressing the return light and improving the efficiency of absorbing excitation light of the active medium.

According to an aspect of the present invention, there is provided a laser apparatus including an active medium, an optical cavity, a wavelength conversion medium, an excitation light source, a first reflector and a second reflector, wherein

the active medium and the wavelength conversion medium are arranged between the first reflector and the second reflector,

excitation light with a center wavelength λ1 emitted from the excitation light source is caused to enter the wavelength conversion medium through the first reflector,

the wavelength conversion medium generates wavelength-converted light with a center wavelength λ2 by the entrance of the excitation light,

the first reflector and the second reflector reflect the wavelength-converted light,

the active medium is photoexcited by at least the wavelength-converted light to emit light, and

the laser apparatus performs optical resonance operation of the light by the optical cavity to generate laser light with a center wavelength λ3.

According to the present invention, a laser apparatus capable of suppressing return light caused in such a manner that part of excitation light reflected by the reflectors is returned to the inside of a semiconductor laser and capable of improving the efficiency of absorbing excitation light of the active medium can be obtained.

Further features of the present invention will become apparent from the following description of exemplary embodiments with reference to the attached drawings.

### BRIEF DESCRIPTION OF THE DRAWINGS

FIG. 1 is a configuration diagram illustrating the configuration of a laser apparatus in an exemplary embodiment 1 of the present invention.

FIG. 2A is a schematic diagram of a configuration used in calculating the light absorptance of an active medium and the rate of return light in the exemplary embodiment 1 of the present invention, FIG. 2B illustrates the results of calculating the light absorptance of the active medium and the rate of return light when a wavelength conversion medium is not provided as a comparative example and when the wavelength conversion medium is provided as the exemplary embodiment 1 of the present invention, and FIG. 2C illustrates the results of calculating the changing rates of the light absorptance of the active medium and the rate of return light when the exemplary embodiment 1 of the present invention and the comparative example are compared.

FIG. 3A is a schematic diagram of a laser apparatus having a configuration used in calculating the light absorptance of an active medium and the rate of return light in an exemplary embodiment 2 of the present invention, and FIG. 3B illustrates the results of calculating the changing rates of the light absorptance of the active medium and the rate of return light when the exemplary embodiment 2 of the present invention and a comparative example are compared.

FIG. 4 is a schematic diagram illustrating an example of a photoacoustic apparatus in an exemplary embodiment 3 of the present invention.

FIGS. 5A, 5B and 5C are configuration examples of laser apparatuses in example 1 of the present invention.

FIGS. 6A and 6B are configuration diagrams illustrating the configurations of laser apparatuses in example 2 of the present invention.

FIG. 7 is a configuration diagram illustrating the configuration of a laser apparatus in example 3 of the present invention.

FIG. 8 is a configuration diagram illustrating the configuration of a laser apparatus in another configuration example of example 3 of the present invention.

### DESCRIPTION OF THE EMBODIMENTS

Preferred embodiments of the present invention will now be described in detail in accordance with the accompanying drawings.

Laser apparatuses in exemplary embodiments of the present invention will be described.

### Exemplary Embodiment 1

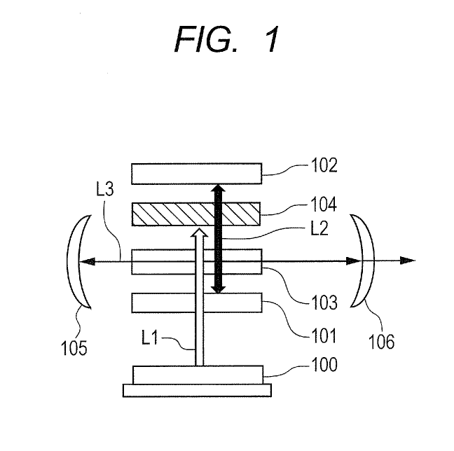

Referring to FIG. 1, a configuration example of a laser apparatus in an exemplary embodiment 1 of the present invention will be described.

In FIG. 1, the laser apparatus includes an excitation light source 100, an active medium 103, a wavelength conversion medium 104, an optical cavity composed of a pair of reflectors 105, 106 opposing to each other through the active medium 103 to cause laser oscillation, and a first reflector 101 and a second reflector 102 as a pair of opposed reflectors.

By the entrance of excitation light L1 with a center wavelength λ1 emitted from the excitation light source 100, the wavelength conversion medium 104 emits wavelength-converted light L2 with a center wavelength λ2 different from the excitation light L1.

The active medium 103 is photoexcited by the absorption of at least wavelength-converted light L2 to emit light, and optical resonance of the light is performed by the optical cavity composed of the reflector 105 and the reflector 106. Thus, the laser apparatus generates laser light L3 with a center wavelength λ3.

The first reflector 101 and the second reflector 102 are disposed in parallel to face each other through the active medium 103 and the wavelength conversion medium 104, thereby constituting the pair of reflectors.

The wavelength conversion medium 104 is arranged between the active medium 103 and the second reflector 102.

The first reflector 101 is designed to transmit at least only part of excitation light L1 and to reflect at least wavelength-converted light L2.

On the other hand, the second reflector 102 is designed to highly reflect at least the wavelength-converted light L2.

The excitation light source 100 is so arranged that the excitation light L1 emitted from the excitation light source 100 is transmitted through the first reflector 101 and at least part of the transmitted excitation light L1 enters the wavelength conversion medium 104.

Next, the influence of the configuration of the laser apparatus in the exemplary embodiment 1 on the photoexcitation process of the active medium 103 will be described.

Referring to FIG. 1, when excitation light L1 emitted from the excitation light source 100 enters the first reflector 101, part of the excitation light L1 is transmitted through the first reflector 101, and the rest is reflected to serve as return light.

At least part of the excitation light L1 transmitted through the first reflector 101 is transmitted through the active medium 103 to enter the wavelength conversion medium 104.

By the entrance of the excitation light L1, the wavelength conversion medium 104 emits wavelength-converted light L2.

The wavelength-converted light L2 is reflected many times by the pair of reflectors composed of the first reflector 101 and the second reflector 102.

Thus, the wavelength-converted light L2 is reflected between the first reflector 101 and the second reflector 102 many times until the transmitted wavelength-converted light L2 without being absorbed into the active medium 103 is absorbed into the active medium 103 without loss. As a result, the light absorptance of the active medium 103 with respect to the wavelength-converted light L2 can be improved.

Here, since the first reflector 101 reflects wavelength-converted light L2, the wavelength-converted light L2 can be prevented from being transmitted through the first reflector 101 to enter the excitation light source 100.

In other words, return light incident on the excitation light source 100 can be suppressed, and hence the operation of the excitation light source 100 can be stabilized.

To confirm the influence of the wavelength conversion medium 104 in the exemplary embodiment 1 on the light absorptance of the active medium 103 and on the return light, the following calculations were made.

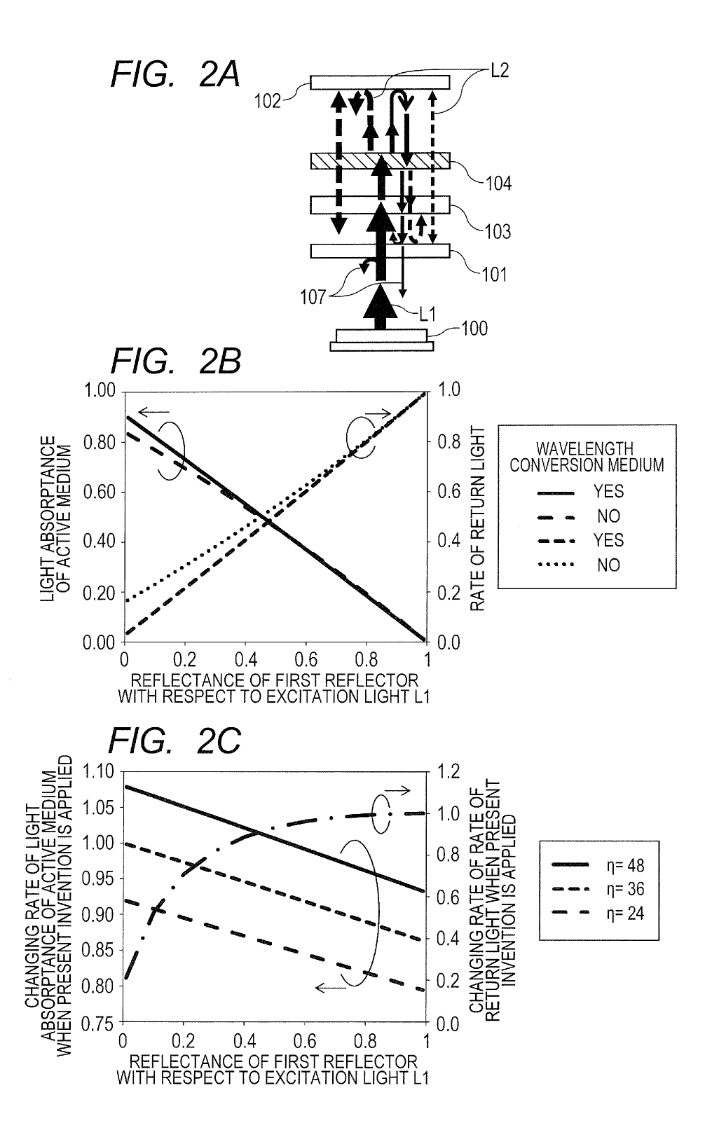

Here, using, as a model configuration, a configuration of the laser apparatus involved in the photoexcitation process as illustrated in FIG. 2A, the calculations were made on the rate at which excitation light L1 emitted from the excitation light source contributes to the light absorption of the active medium 103 and the rate of becoming return light.

The calculations were made by setting the reflectance and absorptance of each constituent element as the following values.

The reflectance of the first reflector 101 with respect to the wavelength-converted light L2 was set to 100%, and the reflectances of the second reflector 102 with respect to the excitation light L1 and the wavelength-converted light L2 were both set to 100%.

Here, since “reflectance”+“transmittance” 100%, the transmittance of the first reflector 101 with respect to the wavelength-converted light L2 was set to 0%, and the transmittances of the second reflector 102 with respect to the excitation light L1 and the wavelength-converted light L2 were both set to 0%.

The absorptances of the active medium 103 with respect to the excitation light L1 and the wavelength-converted light L2 were both set to 60%, and the absorptance of the wavelength conversion medium 104 with respect to the excitation light L1 was set to 60%.

Further, the rates at which the excitation light L1 absorbed into the wavelength conversion medium 104 is converted to the wavelength-converted light L2 were set to three rates of 40%, 60%, and 80%. In other words, when the conversion efficiency with which the excitation light L1 incident on the wavelength conversion medium 104 is converted to the wavelength-converted light L2 is denoted by η, i.e., η=24%, 36%, and 48%.

Further, the absorptance of the wavelength conversion medium 104 with respect to the wavelength-converted light L2 was set to 0%, i.e., it was assumed that the wavelength conversion medium 104 did not reabsorb the wavelength-converted light L2.

Referring to FIG. 2A, when excitation light L1 emitted from the excitation light source 100 enters the first reflector 101, part of the excitation light L1 is transmitted through the first reflector 101 and the rest is reflected to be return light 107.

When the excitation light L1 transmitted through the first reflector 101 enters the active medium 103, part of the excitation light L1 is absorbed into the active medium 103 and the rest is transmitted therethrough.

When the excitation light L1 transmitted through the active medium 103 enters the wavelength conversion medium 104, part of the excitation light L1 is absorbed into the wavelength conversion medium 104, and the wavelength conversion medium 104 generates wavelength-converted light L2.

The excitation light L1 that was not absorbed into the wavelength conversion medium 104 is transmitted through the wavelength conversion medium 104 and is reflected by the second reflector 102 to reenter the wavelength conversion medium 104. Part of the incident excitation light L1 is converted to wavelength-converted light L2 and the rest is transmitted through the wavelength conversion medium 104.

The excitation light L1 transmitted through the wavelength conversion medium 104 reenters the active medium 103, where part of the excitation light L1 is absorbed into the active medium 103 and the rest is transmitted therethrough.

Part of the excitation light L1 transmitted through the active medium 103 is reflected by the first reflector 101, and the rest is transmitted therethrough to be return light 107.

The excitation light L1 reflected by the first reflector 101 is repeatedly reflected, absorbed, and transmitted between the first reflector 101 and the second reflector 102 as mentioned above.

On the other hand, the wavelength-converted light L2 is absorbed into the active medium 103 while being reflected many times between the first reflector 101 and the second reflector 102.

Here, it was assumed that excitation light L1 travels back and forth between the first reflector 101 and the second reflector 102 ten times, and the a value obtained by dividing the total amount of the excitation light L1 and wavelength-converted light L2 absorbed into the active medium 103 during such travelling by the amount of excitation light L1 first emitted from the excitation light source 100 was set as the light absorptance of the active medium 103.

Further, the value obtained by dividing the total amount of excitation light L1 returning to the side of the excitation light source 100 with respect to the first reflector 101 by the amount of excitation light L1 first emitted from the excitation light source 100 was set as the rate of return light.

Calculation results of the light absorptance of the active medium 103 and the rate of return light relative to the reflectance of the first reflector 101 with respect to excitation light L1 when the wavelength conversion medium 104 is not provided (comparative example) and when the wavelength conversion medium 104 is provided (exemplary embodiment 1 of the present invention) in FIG. 2A are illustrated in FIG. 2B.

Here, the calculations were made by setting the conversion efficiency η of the wavelength conversion medium 104 as η=48%.

It is found that, regardless of the presence or absence of the wavelength conversion medium 104, the light absorptance of the active medium 103 monotonically decreases whereas the rate of return light monotonically increases as the reflectance of the first reflector 101 with respect to the excitation light L1 is increased.

This is because only the excitation light L1 transmitted through the first reflector 101 of the excitation light L1 first emitted from the excitation light source 100 is involved in the light absorption process of the wavelength conversion medium 104, and the rest of the excitation light L1 reflected by the first reflector 101 becomes return light. Further, when the reflectance of the first reflector 101 with respect to excitation light L1 is low, the light absorptance of the active medium 103 is more improved when the wavelength conversion medium 104 is provided. However, the degree of improvement in light absorptance decreases as the reflectance of the first reflector 101 with respect to excitation light L1 increases, and when the reflectance is high, the light absorptance decreases by contrast.

On the other hand, the rate of return light decreases by providing the wavelength conversion medium 104, regardless of the reflectance of the first reflector 101 with respect to excitation light L1, indicating that the effect of the present invention is produced. It is also found that the effect of the present invention increases as the reflectance of the first reflector 101 with respect to excitation light L1 decreases.

These results are obtained because excitation light L1 is transmitted through the first reflector 101 when the reflectance of the first reflector 101 is low after the excitation light L1 emitted from the excitation light source 100 is reflected by the second reflector 102 and returned to the first reflector 101, i.e., when the transmittance of the first reflector 101 is high, and hence the excitation light L1 is not involved in the photoexcitation process of the active medium 103 from then on.

In other words, as the reflectance of the first reflector 101 with respect to excitation light L1 decreases, it is better to convert the excitation light L1 to wavelength-converted light L2 through the wavelength conversion medium 104 so that light contributing to the photoexcitation of the active medium 103 can be confined in the pair of reflectors composed of the first reflector 101 and the second reflector 102.

As a result, the light absorptance can be improved while reducing the rate of return light as the reflectance of the first reflector 101 with respect to excitation light L1 decreases.

By contrast, as the reflectance of the first reflector 101 with respect to excitation light L1 increases, the rate of becoming return light in the excitation light L1 returned as a result of being reflected by the second reflector 102 is reduced. Therefore, the effect of reducing the rate of return light by the wavelength conversion medium 104 is reduced.

On the other hand, in the excitation light L1 returned as a result of being reflected by the second reflector 102, the rate of excitation light L1 reflected by the first reflector 101 and involved again in the photoexcitation process of the active medium 103 increases.

Here, when the excitation light L1 is converted to wavelength-converted light L2 by the wavelength conversion medium 104, a conversion loss is caused.

Therefore, when the reflectance of the first reflector 101 with respect to excitation light L1 is high, it is better to let the active medium 103 absorb the excitation light L1 directly without using the wavelength conversion medium 104 rather than let the active medium 103 absorb wavelength-converted light L2, so that light absorptance will increase because of no conversion loss.

Therefore, as the reflectance of the first reflector 101 with respect to excitation light L1 increases, the effect of reducing the rate of return light caused by providing the wavelength conversion medium 104 decreases and the light absorptance decreases by providing the wavelength conversion medium 104.

FIG. 2C illustrates the results of calculating the changing rates of the light absorptance and the rate of return light by dividing a calculated value for the active medium 103 when the wavelength conversion medium 104 is provided (exemplary embodiment 1 of the present invention) by a calculated value when the wavelength conversion medium 104 is not provided (comparative example).

As mentioned above, when the reflectance of the first reflector 101 with respect to excitation light L1 is low, it is found that the rate of return light can be significantly reduced by providing the wavelength conversion medium 104 in the exemplary embodiment 1 of the present invention, compared with the case where the wavelength conversion medium 104 is not provided in the comparative example.

For example, when the reflectance of the first reflector 101 with respect to excitation light L1 is 10% or less, since the wavelength conversion medium 104 is provided in the exemplary embodiment 1 of the present invention, return light can be reduced by 50% or more, compared with the comparative example where the wavelength conversion medium 104 is not provided.

Further, even when the reflectance of the first reflector 101 with respect to excitation light L1 is 10% or more, it is found that the return light can be reduced by providing the wavelength conversion medium 104 in the exemplary embodiment 1 of the present invention.

On the other hand, the light absorptance of the active medium 103 monotonically decreases as the reflectance of the first reflector 101 with respect to excitation light L1 increases.

Further, it is found that the light absorptance decreases as the conversion efficiency η of the wavelength conversion medium 104 decreases.

They are caused by a conversion loss caused when the excitation light L1 is converted to wavelength-converted light L2 by the wavelength conversion medium 104 as mentioned above.

Here, in the case of conversion efficiency n=48%, it is found that, when the reflectance of the first reflector 101 with respect to excitation light L1 is 50% or less, the changing rate of light absorptance of the active medium 103 exceeds 1.0.

In other words, it is found that the light absorptance can be improved by providing the wavelength conversion medium 104 in the exemplary embodiment 1 of the present invention, compared with the comparative example where the wavelength conversion medium 104 is not provided.

This is because the conversion efficiency of the wavelength conversion medium is high, that is, this is because, when the conversion loss is low, the rate of being absorbed into the active medium 103 after the excitation light L1 is converted to the wavelength-converted light L2 exceeds the rate of being lost by the conversion loss as mentioned above.

As described above, it is found that the effect of suppressing return light to the excitation light source 100 can be obtained in the exemplary embodiment compared with the case where the wavelength conversion medium 104 is not provided.

This can stabilize the operation of the excitation light source 100, and as a result, the operation of the laser apparatus can be stabilized.

Further, if the conversion efficiency η is not relatively low, the light absorptance of the active medium can further be improved. As a result, there is also a secondary effect of enabling a further improvement in the characteristics of the laser apparatus.

In the exemplary embodiment, the case where a single excitation light L1 is emitted from the excitation light source 100 is illustrated with reference to FIG. 1.

However, the present invention is not limited to this. For example, multiple semiconductor lasers generating excitation light L1 may be arranged in an array and used as the excitation light source 100.

In the above calculations in the exemplary embodiment, the case where the active medium 103 absorbs excitation light L1 in addition to wavelength-converted light L2 is illustrated.

Since this considerably increases the light absorptance of the active medium 103, it is preferred that the active medium 103 should also absorb the excitation light L1.

Further, the case where the wavelength conversion medium 104 is arranged between the active medium 103 and the second reflector 102 is illustrated.

Since part of the excitation light L1 is lost by the conversion loss, it is better to let excitation light L1 be incident on and absorbed into the active medium 103 before entering the wavelength conversion medium 104 in order to increase the light absorptance of the active medium 103.

Thus, it is preferred to arrange the wavelength conversion medium 104 between the active medium 103 and the second reflector 102 in order to let the excitation light L1 emitted from the excitation light source 100 enter the active medium 103 prior to the wavelength conversion medium 104.

However, the present invention is not limited to this. The wavelength conversion medium 104 may be arranged between the first reflector 101 and the active medium 103.

Further, the present invention is not limited to the case where the active medium 103 absorbs the excitation light L1. The active medium 103 does not have to absorb the excitation light L1.

Further, in the exemplary embodiment, the case where the direction in which wavelength-converted light L2 is reflected many times by the first reflector 101 and the second reflector 102 and the direction in which laser light L3 is emitted are different by 90° is illustrated.

However, the present invention is not limited to this. The direction in which the wavelength-converted light L2 is reflected many times and the direction in which the laser light L3 is emitted may be the same direction or any different directions.

Further, in the exemplary embodiment, the case where the first reflector 101 and the second reflector 102 are arranged in parallel to constitute a pair of reflectors is illustrated.

It is preferred that the first reflector 101 and the second reflector 102 should be arranged in parallel to reflect wavelength-converted light L2 many times using the pair of reflectors in order to improve the light absorptance of the active medium 103.

However, the present invention is not limited to this, and the pair of reflectors can have any other structure as long as the wavelength-converted light L2 is reflected by the pair of reflectors many times so that the wavelength-converted light L2 enters the active medium 103 many times.

Further, in the above calculations in the exemplary embodiment, the case where the reflectance of the second reflector 102 with respect to excitation light L1 is set to 100% is illustrated, but the present invention is not particularly limited to this, and any reflectance may be used.

As mentioned above, since excitation light L1 is repeatedly reflected between the first reflector 101 and the second reflector 102 by increasing the reflectance of the second reflector 102 with respect to the excitation light L1, the light absorptance of the active medium 103 can be increased.

Therefore, it is preferred to increase the reflectance of the second reflector 102 with respect to excitation light L1 in order to increase the light absorptance.

On the other hand, since the return light can be reduced by decreasing the reflectance of the first reflector 101 with respect to excitation light L1, it is preferred to decrease the reflectance of the first reflector 101 with respect to excitation light L1 in order to further reduce the return light.

Further, in the above calculations in the exemplary embodiment, the case where the reflectances of the first reflector 101 and the second reflector 102 with respect to wavelength-converted light L2 are both set to 100% is illustrated.

Since this can increase the light absorptance of the active medium 103, it is preferred that these reflectances should be high. More specifically, it is preferred that the reflectances of the first reflector 101 and the second reflector 102 with respect to wavelength-converted light L2 should be 90% or more. It is more preferred that the reflectances of the first reflector 101 and the second reflector 102 with respect to wavelength-converted light L2 should be 99.9% or more.

It is preferred that the first reflector 101 should have a reflectance of 99.8% or less with respect to excitation light L1, and it is more preferred that the first reflector 101 should have a reflectance of 50% or less with respect to excitation light L1. Optimally, the reflectance of the first reflector 101 with respect to excitation light L1 is 10% or less. The reflectance of the first reflector 101 with respect to excitation light L1 has only to be appropriately set in view of the amount of incidence of light emitted from the excitation light source 100 on the active medium 103, the reflectance of the second reflector 102 with respect to excitation light L1, and the like.

However, the present invention is not limited to these, and the reflectances of the first reflector 101 and the second reflector 102 with respect to the wavelength-converted light L2 may be set arbitrarily.

### Exemplary Embodiment 2

In an exemplary embodiment 2 of the present invention, a case where such a configuration that the excitation light source 100 and the first reflector 101 are integrated is applied to the present invention will be described, unlike the case of the exemplary embodiment 1 where the excitation light source 100 is put in a position away from the first reflector 101.

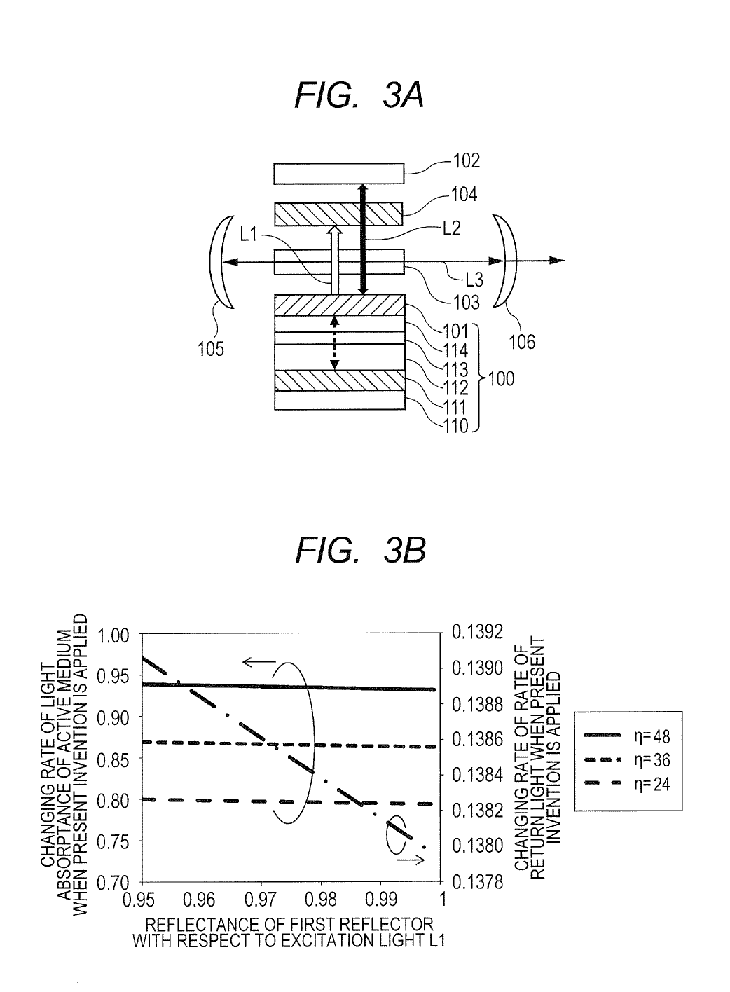

In other words, a case where the first reflector 101 serves also as one of the reflectors that constitute a cavity of the excitation light source 100 made up of a semiconductor laser will be described with reference to FIG. 3A.

In FIG. 3A, the excitation light source 100 is made up of a vertical cavity surface emitting laser (which may be abbreviated as VCSEL below) and includes a substrate 110, a lower reflector 111, a lower clad layer 112, an active layer 113, an upper clad layer 114, and a first reflector 101 functioning also as an upper reflector.

The lower reflector 111 is designed to highly reflect light from the active layer 113. Further, the first reflector 101 is designed to highly reflect light from the active layer 113 and wavelength-converted light L2.

For example, such a first reflector 101 can be made up of a distributed Bragg reflector (which may be abbreviated as DBR below) composed of dielectric multi-layers.

Light emitted from the active layer 113 is resonated and amplified between the lower reflector 111 and the first reflector 101, and the excitation light L1, which is coherent light, is surface-emitted in a direction perpendicular to the surface of the first reflector 101.

Note that the reflectance of the first reflector 101 in the exemplary embodiment 2 is set lower than the reflectance of the lower reflector 111 in order to cause the excitation light L1 from the excitation light source 100 to exit from the side of the upper reflector 101.

Next, the influence of the configuration of the laser apparatus in the exemplary embodiment 2 on the photoexcitation process of the active medium 103 will be described.

Unlike in the exemplary embodiment 1, excitation light L1 from the excitation light source 100 is emitted from the first reflector 101 in the exemplary embodiment 2.

Therefore, only light having transmitted through the active medium 103 and then transmitted through the first reflector 101 becomes return light.

To confirm the influence of the wavelength conversion medium 104 according to the exemplary embodiment 2 on the light absorptance of the active medium 103 and on the return light, the following calculations were made.

In other words, the results of calculating the changing rates of the light absorptance and the rate of return light in the same way as in the exemplary embodiment 1 by dividing a calculated value for the active medium 103 when the wavelength conversion medium 104 is provided (exemplary embodiment 2 of the present invention) by a calculated value when the wavelength conversion medium 104 is not provided (comparative example) are illustrated in FIG. 3B.

According to the exemplary embodiment 2, it is found that the rate of return light can be reduced to 1/7 or less by providing the wavelength conversion medium 104, compared with the comparative example in which the wavelength conversion medium 104 is not provided.

In the exemplary embodiment 2, the case where the excitation light source 100 is the VCSEL is illustrated, but the present invention is not particularly limited to this. For example, it may be an edge emitting laser.

In such a case, the edge emitting laser is so designed that one edge reflector of a pair of edge reflectors that constitute an optical cavity of the edge emitting laser can highly reflect light from the active layer 113 and wavelength-converted light L2.

Such an edge reflector can be made, for example, by forming a DBR film made up of dielectric multi-layers on an edge of the edge emitting laser on the side of emitting excitation light L1.

### Exemplary Embodiment 3

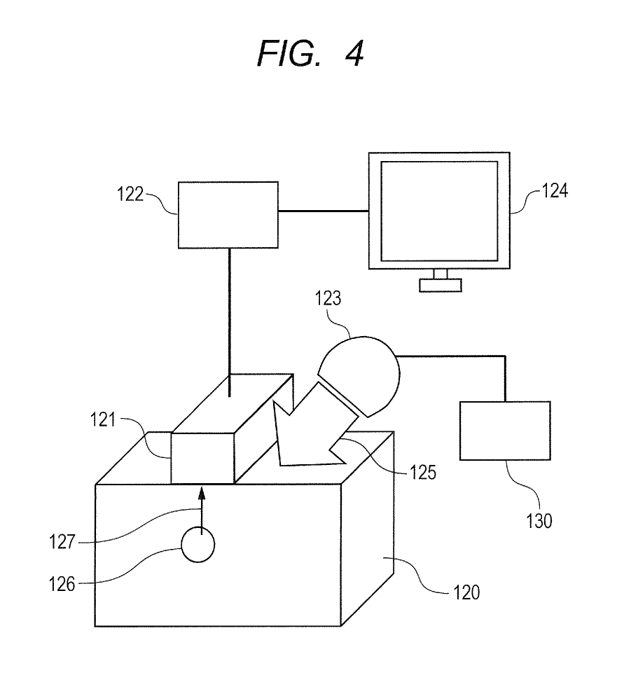

In the exemplary embodiment, an information acquisition apparatus using the laser apparatus of the exemplary embodiment 1 or 2 will be described with reference to FIG. 4. As an example of the information acquisition apparatus, a photoacoustic apparatus is described. The photoacoustic apparatus has a laser apparatus 130, a probe 121 for detecting an elastic wave generated by irradiating a subject 120 with light emitted by the laser apparatus 130 to convert the elastic wave to an electric signal, and an acquisition unit 122 for acquiring information on the optical properties of the subject 120 based on the electric signal. The photoacoustic apparatus also has an optical system 123 for irradiating the subject 120 with the light emitted by the laser apparatus 130. Further, the photoacoustic apparatus may have a display unit 124 for displaying information acquired by the acquisition unit 122.

The light emitted by the laser apparatus 130 is irradiated to the subject 120 as pulsed light 125 through the optical system 123. Then, a photoacoustic wave 127 is generated by an optical absorber 126 in the subject 120 due to a photoacoustic effect. Then, the probe 121 detects the photoacoustic wave 127 having propagated inside the subject 120 to acquire time-series electric signals. Then, the acquisition unit 122 acquires information on the inside of the subject 120 based on the time-series electric signals, and displays, on the display unit 124, the information on the inside of the subject 120.

It is desired that the wavelength of light capable of being emitted by the laser apparatus 130 should be a wavelength of light that can propagate inside the subject 120. Specifically, when the subject 120 is a biological body, the optimum wavelength is in a range of not less than 130 nm and not more than 1200 nm. However, when information on the optical properties of body tissues relatively near the surface of the biological body is acquired, a range wider than the above wavelength range, for example, a wavelength range of not less than 400 nm and not more than 1600 nm can also be used.

The information on the optical properties of the subject includes the initial acoustic pressure of the photoacoustic wave, the light energy absorption density, the absorption coefficient, the concentrations of substances constituting the subject, and the like. Here, the concentrations of substances include oxygen saturation, oxyhemoglobin concentration, deoxyhemoglobin concentration, total hemoglobin concentration, and the like. The total hemoglobin concentration is the sum of oxyhemoglobin concentration and deoxyhemoglobin concentration. In the exemplary embodiment, the information on the optical properties of the subject may be distribution information on each position inside the subject, rather than numerical data. In other words, the acquisition unit 122 may acquire distribution information, such as an absorption coefficient distribution or oxygen saturation distribution, as the information on the optical properties of the subject.

### EXAMPLES

Next, examples of the present invention will be described.

### Example 1

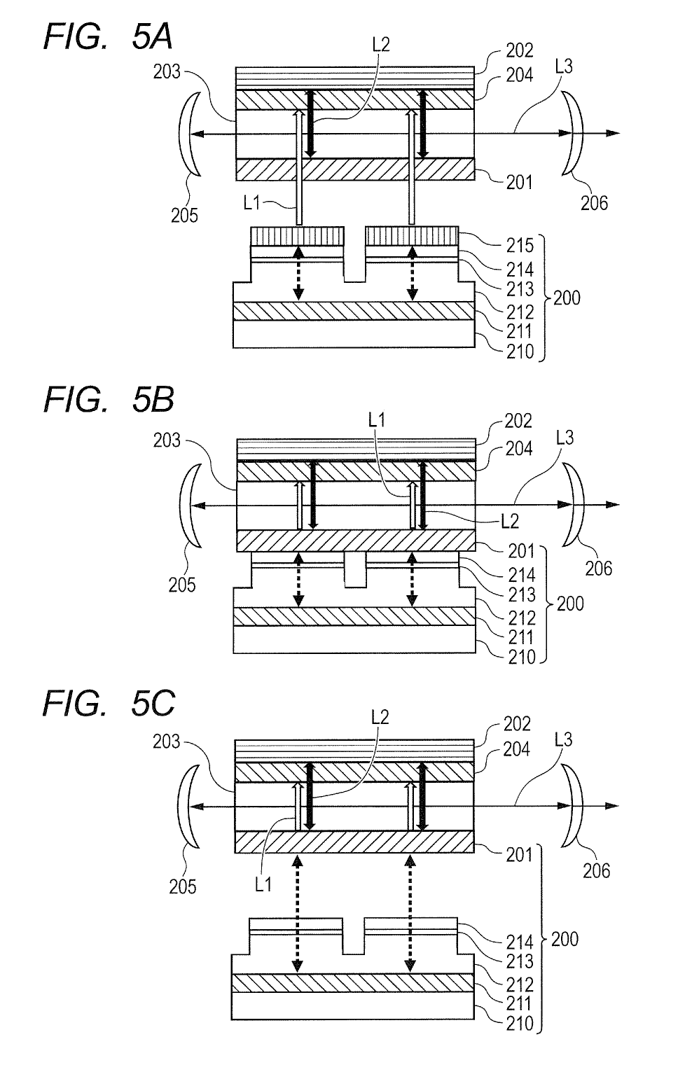

A configuration example of a laser apparatus as configured by applying the present invention will be described as example 1 with reference to FIG. 5A.

The laser apparatus of the example includes an excitation light source 200, a first reflector 201, a second reflector 202, an active medium 203, a wavelength conversion medium 204, and a pair of reflectors 205, 206.

The reflector 205 and the reflector 206 are arranged opposite to each other through the active medium 203 to constitute an optical cavity for laser oscillation.

The excitation light source 200 is made up of a VCSEL array in which multiple VCSELs are arranged in an array and includes a base substrate 210, a lower reflector 211, a lower clad layer 212, an active layer 213, an upper clad layer 214, and an upper reflector 215.

The lower reflector 211 and the upper reflector 215 constitute an optical cavity of the VCSELs.

The VCSELs are made of a nitride semiconductor.

The base substrate 210 is made of an n-type GaN substrate.

The lower clad layer 212 and the upper clad layer 214 are made of n-type and p-type GaN, respectively.

The active layer 213 has a multiquantum well structure using a nitride semiconductor material, and the well layer and the barrier layer of the quantum well structure are made of InGaN and GaN, respectively. Here, x=0.1.

The band gap of the well layer is smaller than the band gaps of the barrier layer, the lower clad layer 212, and the upper clad layer 214.

The active layer 213 emits light by carrier injection. The active layer 213 in the example has the multiquantum well structure mentioned above, but it may have a single quantum well structure.

The lower reflector 211 is made up of a nitride semiconductor DBR made by alternately laminating GaN and AlGaN for 60 cycles with an optical thickness of λ/4.

Note that the materials of the lower reflector 211 in the example are not particularly limited to GaN and AlGaN. For example, other materials such as InGaN and AlGaN can be used.

Further, the number of cycles of the nitride semiconductor DBR (GaN and AlGaN) that makes up the lower reflector 211 in the example is 60 cycles, but the present invention is not particularly limited to this, and it may be any number of cycles with which a desired reflectance can be obtained.

Further, the lower reflector 211 in the example is made up of a combination of GaN with the optical thickness of λ/4 and AlGaN with the optical thickness of λ/4, but the present invention is not particularly limited to this, and it may have any other structure with which a desired reflectance can be obtained.

The upper reflector 215 is made up of a dielectric DBR made by alternately laminating SiO₂ and Ta₂O₅ for 13 cycles with an optical thickness of λ/4.

Note that the number of cycles of the dielectric DBR that makes up the upper reflector 215 in the example is 13 cycles, but the present invention is not particularly limited to this, and it may be any number of cycles as long as the materials are laminated at least for one cycle or more and a desired reflectance can be obtained.

Further, the materials of the dielectric DBR that makes up the upper reflector 215 in the example are not particularly limited to SiO₂ and Ta₂O₅, and other materials may be used.

For example, zirconium dioxide (ZrO₂), silicon nitride (SiₓN_{y}), titanium oxide (TiₓO_{y}), MgF₂, CaF₂, BaF₂, Al₂O₃, LiF, and the like can be used.

Further, the upper reflector 215 in the example is made up of the dielectric DBR, but the present invention is not particularly limited to this, and it may be made with any other material.

For example, the upper reflector 215 may be made with a nitride semiconductor like the lower reflector 211.

Note that the reflectance of the upper reflector 215 in the example is set lower than the reflectance of the lower reflector 211 to cause laser light from the VCSELs, namely, excitation light L1, to exit from the side of the upper reflector 215.

The active layer 213 emits light by carrier injection, and the light is resonated and amplified between the lower reflector 211 and the upper reflector 215 so that the excitation light L1 as coherent light with a center wavelength λ1=400 nm will be surface-emitted in a direction perpendicular to the surface of the upper reflector 215.

The first reflector 201 and the second reflector 202 are arranged opposite to each other through the active medium 203 and the wavelength conversion medium 204 to constitute a pair of reflectors.

The active medium 203 is a solid-state laser crystal made of an alexandrite crystal having a slab shape.

The first reflector 201 is formed by depositing the dielectric DBR on a surface on which excitation light L1 from the excitation light source 200 to the active medium 203 is incident.

The second reflector 202 and the wavelength conversion medium 204 are made up as follows.

Namely, the second reflector 202 made up of the nitride semiconductor DBR is formed on the base substrate, and the wavelength conversion medium 204 made of a nitride semiconductor material is formed on the second reflector 202.

The wavelength conversion medium 204 has a multiquantum well structure, and the well layer and the barrier layer of the quantum well structure are made of In_{y}Ga_{1-y}N and GaN, respectively. Here, y=0.2.

Next, a surface of the active medium 203 on the opposite side of the surface on which the first reflector 201 is formed is bonded to a surface of the wavelength conversion medium 204 on the opposite side of the surface on which the second reflector 202 is formed.

Thus, the pair of reflectors composed of the first reflector 201 and the second reflector 202 through the active medium 203 and the wavelength conversion medium 204 are formed.

The first reflector 201 made up of the dielectric DBR is made by alternately laminating SiO₂ and Ta₂O₅ for 13 cycles with an optical thickness of λ/4, and is so designed as to transmit almost 100% of light with a wavelength of 400 nm and reflect 99.9% of light with a wavelength of 440 nm.

Note that the number of cycles of the dielectric DBR that makes up the first reflector 201 in the example is 13 cycles, but the present invention is not particularly limited to this, and it may be any number of cycles as long as the materials are laminated at least for one cycle or more and a desired reflectance can be obtained.

Further, the materials of the dielectric DBR that makes up the first reflector 201 in the example are not particularly limited to SiO₂ and Ta2O₅, and other materials may be used.

For example, zirconium dioxide (ZrO₂), silicon nitride (SiₓN_{y}), titanium oxide (TiₓO_{y}), MgF₂, CaF₂, BaF₂, Al₂O₃, LiF, and the like can be used.

Further, the first reflector 201 in the example is made up of the dielectric DBR, but the present invention is not particularly limited to this, and it may be made with any other material.

For example, the first reflector 201 may be made with a nitride semiconductor like the second reflector 202.

In this case, a nitride semiconductor DBR having a desired reflectance is formed on a base substrate made of a material, such as sapphire, which transmits light with a wavelength of 400 nm. Next, a surface on which the excitation light L1 of the active medium 203 from the excitation light source 200 is incident and the surface of the nitride semiconductor DBR are bonded to each other so that the first reflector 201 can be formed.

Further, the second reflector 202 made up of the nitride semiconductor DBR is made by alternately laminating GaN and AlGaN for 80 cycles with an optical thickness of λ/4, and is so designed as to reflect 99.9% of light with a wavelength of 400 nm and a wavelength of 440 nm.

Note that the number of cycles of the nitride semiconductor that makes up the second reflector 202 in the example is 80 cycles, but the present invention is not particularly limited to this, it may be any number of cycles as long as the materials are laminated at least for one cycle or more and a desired reflectance can be obtained.

Multiple excitation lights L1 with a center wavelength λ1=400 nm emitted from the excitation light source 200 made up of the VCSEL array transmit through the first reflector 201 to enter the active medium 203.

The active medium 203 absorbs part of the incident excitation light L1 to generate a broad emission around a wavelength of 750 nm.

The excitation light L1 having transmitted through the active medium 203 without being absorbed into the active medium 203 enters the wavelength conversion medium 204.

The wavelength conversion medium 204 absorbs part of the incident excitation light L1 to generate, as photoluminescence, wavelength-converted light L2 with a center wavelength λ2=440 nm.

The active medium 203 absorbs part of the wavelength-converted light L2 to generate a broad emission around a wavelength of 750 nm.

The excitation light L1 having transmitted through the wavelength conversion medium 204 without being absorbed into the wavelength conversion medium 204 is reflected by the second reflector 202 to reenter the wavelength conversion medium 204, and part thereof is absorbed to generate the wavelength-converted light L2.

The excitation light L1 having transmitted through the wavelength conversion medium 204 again without being absorbed into the wavelength conversion medium 204 reenters the active medium 203, and part thereof is absorbed to generate a broad emission.

The excitation light L1 having transmitted through the active medium 203 again without being absorbed into the active medium 203 transmits through the first reflector 201 to become return light.

On the other hand, the wavelength-converted light L2 is efficiently absorbed into the active medium 203 while being reflected many times between the first reflector 201 and the second reflector 202 to generate the broad emission. The broad emission light emitted from the active medium 203 is optically resonated by an optical cavity composed of the reflector 205 and the reflector 206 arranged so as to perform optical resonance operation in a direction different by 90 degrees from the incident direction of the excitation light L1 to generate laser light L3 with a center wavelength λ3=755 nm.

The excitation light L1 is converted to the wavelength-converted light L2 by the wavelength conversion medium 204 as mentioned above, and this can significantly reduce return light to the excitation light source 200.

The relations among the center wavelength λ1, the center wavelength λ2, and the center wavelength λ3 are λ3>λ2>λ1.

In the example, the active medium 203, the wavelength conversion medium 204, the first reflector 201, and the second reflector 202 are set to come close to one another, but the present invention is not particularly limited to this, and they may be separated from one another as illustrated in FIG. 1.

Further, the shape of the active medium 203 in the example is a slab shape, but the present invention is not particularly limited to this, and it may be any other shape.

Further, the wavelength conversion medium 204 in the example has the multiquantum well structure made of the nitride semiconductor for generating wavelength-converted light L2 with the center wavelength λ2, but the present invention is not particularly limited to this.

The center wavelength λ2 may be any other wavelength, and the wavelength conversion medium 204 may have any other structure and be made of any other material as long as the wavelength conversion medium 204 generates light capable of photoexciting the active medium 203 to generate laser light L3.

Further, the excitation light source 200 in the example is composed of VCSELs made of the nitride semiconductor for generating excitation light L1 with a center wavelength λ1=400 nm, but the present invention is not particularly limited to this.

The center wavelength λ1 may be any other wavelength, and the excitation light source 200 may be made of any other material as long as the excitation light source 200 generates excitation light L1 capable of photoexciting the wavelength conversion medium 204 to generate wavelength-converted light L2.

Further, the excitation light source 200 in the example generates excitation light L1 capable of photoexciting the active medium 203 directly, but the present invention is not particularly limited to this.

Although it is preferred to generate excitation light L1 capable of photoexciting the active medium 203 directly in order to increase the light absorptance of the active medium 203, the effects of the present invention can be obtained even if excitation light L1 incapable of photoexciting the active medium 203 directly is generated.

Further, the excitation light source 200 in the example is the VCSEL array, but the present invention is not particularly limited to this, it may be a single VCSEL, an edge emitting laser, or a light-emitting diode.

Further, the reflectances of the first reflector 201 and the second reflector 202 with respect to wavelength-converted light L2 in the example are 99.9%, respectively, but the present invention is not particularly limited to this. Although it is preferred that the reflectance with respect to the wavelength-converted light L2 should be high in order to increase the light absorptance of the active medium 203, the effects of the present invention can be obtained even if the reflectance is low.

Note that the active medium 203 in the example is the solid-state laser crystal made of an alexandrite crystal, but the present invention is not particularly limited to this. For example, a solid-state laser crystal made of a Cr:LiSAF crystal or a Cr:LiCAF crystal may be used, and an active medium 203 for generating laser light L3 with a desired center wavelength λ3 may be used.

In this case, the structure of the excitation light source 200 is also altered according to the properties of the active medium 203.

For example, when laser light L3 with λ3=1064 nm is desired, the active medium 203 uses a solid-state laser crystal made of a Nd:YAG crystal, Nd:YVO₄ crystal, or Nd:GdVO₄ crystal. Further, the excitation light source 200 uses, for example, a VCSEL array made of InAlGaAs for generating excitation light L1 with λ1=808 nm.

Further, when laser light L3 with λ3=700 to 850 nm is desired, the active medium 203 uses, for example, a solid-state laser crystal made of a Ti:Sapphire crystal. Further, the excitation light source 200 uses, for example, a solid-state green laser for generating excitation light L1 with λ1=532 nm, or a VCSEL array made of InGaN for generating excitation light L1 with λ1=450 nm.

Next referring to FIG. 5B and FIG. 5C, other configuration examples in the example will be described.

A configuration example in which the first reflector serves also as the upper reflector of VCSELs to constitute the excitation light source will be described with reference to FIG. 5B.

Referring to FIG. 5B, the first reflector 201 serves also as the upper reflector of VCSELs arranged in an array to constitute the excitation light source 200.

The first reflector 201 thus configured is made up of a dielectric DBR so designed as to reflect 99.8% of light with the center wavelength λ1 and 99.9% of light with the center wavelength λ2.

Note that the reflectance of the first reflector 201 in the configuration example with respect to the center wavelength λ1 is set lower than the reflectance of the lower reflector 211 to cause laser light from the VCSELs, namely, excitation light L1, to exit from the side of the first reflector 201.

In the configuration example, excitation light L1 from the excitation light source 200 can enter the active medium 203 without any space therebetween.

This can suppress an optical loss of the excitation light L1 cause by passing through the space, and hence it is expected to improve the light absorptance of the active medium 203. Such a secondary effect that the entire laser apparatus can be downsized can also be expected.

Note that the excitation light source 200 in the configuration example is made up of VCSELs, but the present invention is not particularly limited to this. For example, as illustrated in FIG. 5C, the excitation light source 200 may be made up of an vertical external cavity surface emitting laser (which may be abbreviated as VECSEL below) in which the first reflector 201 serving also as the upper reflector of the VCSELs is externally placed.

### Example 2

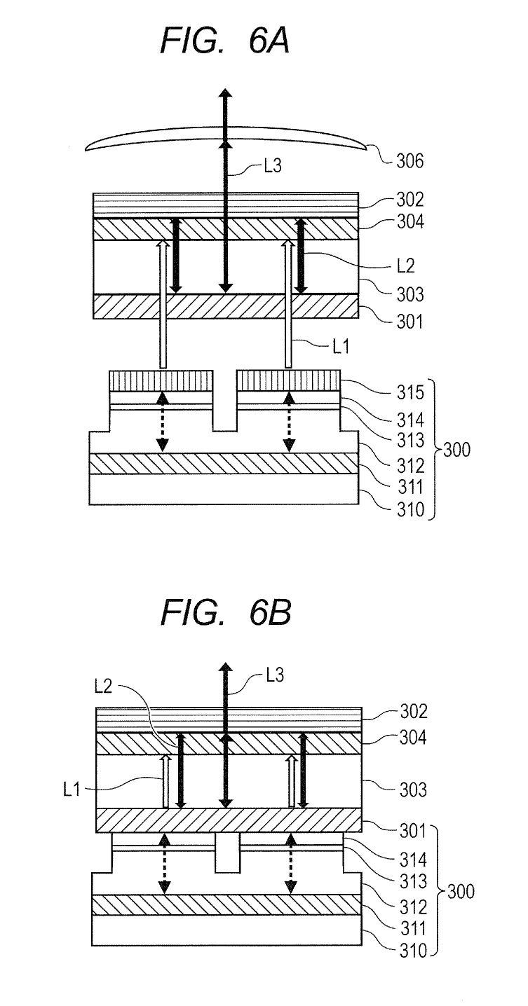

In example 2, a laser apparatus having a disk laser structure using an active medium having a disk shape will be described with reference to FIG. 6A.

Referring to FIG. 6A, the laser apparatus of the example includes an excitation light source 300, a first reflector 301, a second reflector 302, an active medium 303, a wavelength conversion medium 304, and a pair of reflectors composed of the first reflector 301 and a reflector 306 to constitute an optical cavity for generating laser L3 with the center wavelength λ3.

Further, the first reflector 301 also constitutes, together with the second reflector 302, a pair of reflectors for reflecting wavelength-converted light L2 with the center wavelength λ2.

In other words, the first reflector 301 is so designed as to reflect lights of λ2 and λ3, respectively.

The active medium 303 has a disk shape, is photoexcited by the absorption of at least wavelength-converted light L2, and performs optical resonance operation by the optical cavity composed of the first reflector 301 and the reflector 306 to generate laser light L3.

The excitation light source 300 is made up of a VCSEL array in which multiple VCSELs are arranged in an array and includes a base substrate 310, a lower reflector 311, a lower clad layer 312, an active layer 313, an upper clad layer 314, and an upper reflector 315.

The lower reflector 311 and the upper reflector 315 constitute an optical cavity of the VCSELs.

Excitation light L1 emitted from the excitation light source 300 transmits through the first reflector 301 to enter the active medium 303.

The active medium 303 absorbs part of the incident excitation light L1 and is photoexcited.

The excitation light L1 having transmitted through the active medium 303 without being absorbed into the active medium 303 enters the wavelength conversion medium 304.

The wavelength conversion medium 304 absorbs part of the incident excitation light L1 to generate wavelength-converted light L2.

The active medium 303 absorbs part of the wavelength-converted light L2 and is photoexcited.

The wavelength-converted light L2 is efficiently absorbed into the active medium 303 while being reflected many times between the first reflector 301 and the second reflector 302 to photoexcite the active medium 303.

Light generated by the light excitation and emitted from the active medium 303 is optically resonated by the optical cavity composed of the first reflector 301 and the reflector 306 to generate laser light L3. The relations among λ1, λ2, and λ3 are λ3>λ2>λ1.

Thus, since the excitation light L1 is converted to the wavelength-converted light L2 and the first reflector 301 reflects the wavelength-converted light L2, the wavelength-converted light L2 is suppressed from transmitting through the first reflector 301 to enter the excitation light source 300.

In other words, return light to the excitation light source 300 can be suppressed, and hence the operation of the excitation light source 300 can be stabilized.

Note that the laser apparatus in the example has a disk laser structure in which the active medium 303 is in the shape of a disk, but the present invention is not particularly limited to this. For example, it may be a laser apparatus having a rod laser structure in which the active medium 303 is in the shape of a rod.

Next, another configuration example in the example will be described.

In FIG. 6B, the first reflector 301 and the second reflector 302 not only constitute an optical cavity for generating laser light L3 but also function as a pair of reflectors for reflecting wavelength-converted light L2 many times.

In other words, the first reflector 301 is so designed as to serve also as one reflector of the pair of reflectors that constitute the optical cavity in order to reflect light of λ2 and light of λ3, respectively. Further, the second reflector 302 is so designed as to serve also as the other reflector of the pair of reflectors that constitute the optical cavity in order to reflect light of λ2 and light of λ3, respectively.

Note that the reflectance of the second reflector 302 with respect to light of λ3 is set lower than the reflectance of the first reflector 301 with respect to light of λ3 in order cause laser light L3 to exit from the side of the second reflector 302.

Further, the first reflector 301 serves also as the upper reflector of VCSELs that constitute the excitation light source 300.

In other words, the first reflector 301 is so designed as to reflect light of λ1 as well.

This can reduce the number of parts of the laser apparatus, and hence it can be expected to downsize the entire laser apparatus.

### Example 3

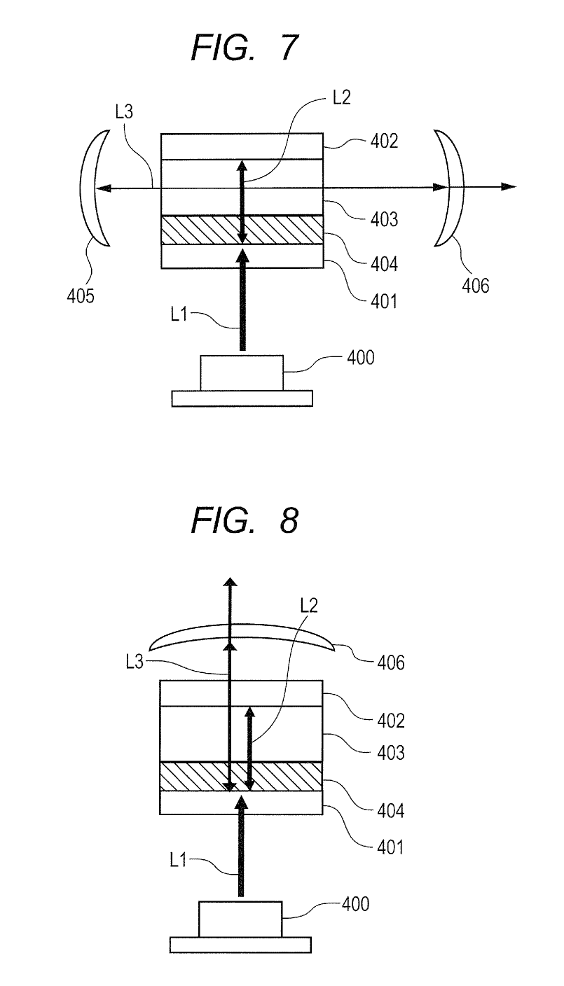

In example 3, a laser apparatus using a non-linear optical crystal for the wavelength conversion medium will be described with reference to FIG. 7.

Referring to FIG. 7, the laser apparatus of the example includes an excitation light source 400, a first reflector 401, a second reflector 402, an active medium 403, a wavelength conversion medium 404, and a pair of reflectors 405, 406.

The reflector 405 and the reflector 406 are arranged opposite to each other through the active medium 403 to constitute an optical cavity for generating laser light L3 with a center wavelength λ3.

The excitation light source 400 is an Nd:YAG laser for generating excitation light L1 with a center wavelength λ1=1064 nm, which is configured to photoexcite a solid-state laser crystal made of a Nd:YAG crystal using a semiconductor laser with a center wavelength of 808 nm so as to generate the excitation light L1.

The active medium 403 is made of a Ti:Sapphire crystal, and the wavelength conversion medium 404 is made of a beta barium borate crystal (β-BaB₂O₄ crystal, which may be abbreviated as BBO crystal below) for generating harmonic wave light.

The first reflector 401 and the second reflector 402 are each made of dielectric DBR and designed to transmit almost 100% of light with λ1=1064 nm and reflect 99.9% of light with λ2=532 nm.

Excitation light L1 with λ1=1064 nm emitted from the excitation light source 400 transmits through the first reflector 401 to enter the wavelength conversion medium 404.

By the incidence of the excitation light L1, the wavelength conversion medium 404 generates second harmonic wave light, i.e., wavelength-converted light L2 with λ2=532 nm.

The wavelength-converted light L2 efficiently photoexcites the active medium 403 while being reflected many times between the first reflector 401 and the second reflector 402 to generate the laser light L3 by the optical cavity composed of the reflector 405 and the reflector 406.

Thus, the excitation light L1 is converted to the wavelength-converted light L2 by the wavelength conversion medium 404, and this can significantly reduce return light to the excitation light source 400.

The relation between the center wavelength λ1 and the center wavelength λ2 is λ2<λ1, and the relation between the center wavelength λ2 and the center wavelength λ3 is λ3>λ2.

Note that the active medium 403 in example 3 is a solid-state laser crystal made of a Ti:Sapphire crystal, but the present invention is not particularly limited to this, and an active medium 403 for generating laser light L3 with a desired center wavelength λ3 has only to be used.

Further, wavelength-converted light L2 in example 3 is second harmonic wave light generated by using the BBO crystal for the wavelength conversion medium 404, but the present invention is not particularly limited to this.

For example, the wavelength-converted light L2 may be third harmonic wave light, sum frequency light, or parametric light as long as the wavelength-converted light L2 can photoexcite the active medium 403.

In this case, a non-linear optical crystal that constitutes the wavelength conversion medium 404 and an excitation light source 400 according to desired wavelength-converted light L2 are used.

For example, when sum frequency light is used as the wavelength-converted light L2, the excitation light source 400 is composed of two kinds of light sources different in wavelength.

Next, another configuration example in example 3 will be described.

In FIG. 8, a first reflector 401 and a reflector 406 constitute an optical cavity for generating laser light L3.

Further, the first reflector 401 and a second reflector 402 constitute a pair of reflectors for reflecting wavelength-converted light L2 many times.

In other words, the first reflector 401 is so designed as to reflect lights of λ2 and λ3.

This can reduce the number of parts of the laser apparatus, and hence it can be expected to downsize the entire laser apparatus.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-204453, filed Oct. 3, 2014, which is hereby incorporated by reference herein in its entirety.

What is claimed is:

1. A laser apparatus comprising an active medium, an optical cavity, a wavelength conversion medium, an excitation light source, a first reflector and a second reflector, wherein
the active medium and the wavelength conversion medium are arranged between the first reflector and the second reflector,
excitation light with a center wavelength λ1 emitted from the excitation light source is caused to enter the wavelength conversion medium through the first reflector,
the wavelength conversion medium generates wavelength-converted light with a center wavelength λ2 by entrance of the excitation light,
the first reflector and the second reflector reflect the wavelength-converted light,
the active medium is photoexcited by at least the wavelength-converted light to emit light, and
the laser apparatus causes resonance of the light by the optical cavity to generate laser light with a center wavelength λ3.

2. The laser apparatus according to claim 1, wherein the excitation light is laser light.

3. The laser apparatus according to claim 1, wherein relations among the center wavelength λ1, the center wavelength λ2, and the center wavelength λ3 are λ3>λ2>λ1.

4. The laser apparatus according to claim 3, wherein the wavelength conversion medium is made of a semiconductor material.

5. The laser apparatus according to claim 4, wherein the wavelength conversion medium has a quantum well structure.

6. The laser apparatus according to claim 1, wherein relation between the center wavelength λ1 and the center wavelength λ2 is λ2<λ1, and relation between the center wavelength λ2 and the center wavelength λ3 is λ3>λ2.

7. The laser apparatus according to claim 6, wherein the wavelength conversion medium is a non-linear optical crystal.

8. The laser apparatus according to claim 7, wherein the wavelength-converted light is selected from the group consisting of harmonic wave light, sum frequency light, and parametric light.

9. The laser apparatus according to claim 1, wherein the active medium is photoexcited by the wavelength-converted light and the excitation light to emit light.

10. The laser apparatus according to claim 9, wherein the wavelength conversion medium is arranged between the active medium and the second reflector.

11. The laser apparatus according to claim 1, wherein the second reflector reflects the excitation light.

12. The laser apparatus according to claim 1, wherein the optical cavity comprises a pair of reflectors.

13. The laser apparatus according to claim 12, wherein the first reflector serves also as one reflector of the pair of reflectors that constitute the optical cavity.

14. The laser apparatus according to claim 13, wherein the second reflector serves also as the other reflector of the pair of reflectors that constitute the optical cavity.

15. The laser apparatus according to claim 1, wherein the excitation light source is a vertical cavity surface emitting laser.

16. The laser apparatus according to claim 15, wherein the first reflector serves also as one reflector of a pair of reflectors that constitute an optical cavity of the vertical cavity surface emitting laser.

17. The laser apparatus according to claim 1, wherein the first reflector and the second reflector have a reflectance of 90% or more with respect to wavelength-converted light.

18. The laser apparatus according to claim 1, wherein the first reflector has a reflectance of 99.8% or less with respect to the center wavelength λ1.

19. The laser apparatus according to claim 1, wherein the first reflector has a reflectance of 50% or less with respect to the center wavelength λ1.

20. An information acquisition apparatus, comprising:
a laser apparatus;
a probe for detecting an elastic wave generated by irradiating a subject with light emitted from the laser apparatus and converting the elastic wave to an electric signal; and
an acquisition unit for acquiring information on optical properties of the subject based on the electric signal, wherein
the laser apparatus includes an active medium, an optical cavity, a wavelength conversion medium, an excitation light source, a first reflector and a second reflector,
the active medium and the wavelength conversion medium are arranged between the first reflector and the second reflector,
excitation light with a center wavelength λ1 emitted from the excitation light source is caused to enter the wavelength conversion medium through the first reflector,
the wavelength conversion medium generates wavelength-converted light with a center wavelength λ2 by entrance of the excitation light,
the first reflector and the second reflector reflect the wavelength-converted light,
the active medium is photoexcited by at least the wavelength-converted light to emit light, and
the laser apparatus causes resonance of the light by the optical cavity to generate laser light with a center wavelength λ3.
